(19) United States
(12) Patent Application Publication
(10) Pub. No.: US 2023/0058791 A1
(43) Pub. Date: Feb. 23, 2023

(54) METHOD FOR SIMULATING DEVELOPMENT DATE BASED ON RESPONSE MECHANISM AND ADAPTATION MECHANISM OF CROP TO ENVIRONMENT

(71) Applicants: CHINESE ACADEMY OF METEOROLOGICAL SCIENCES, Beijing (CN); NORTHWEST A&F UNIVERSITY, Xianyang, Shaanxi (CN)

(72) Inventors: Dingrong WU, Beijing (CN); Qiang YU, Shaanxi (CN); Peijuan WANG, Beijing (CN); Zhiguo HUO, Beijing (CN); Yanling SONG, Beijing (CN); Jianying YANG, Beijing (CN)

(73) Assignees: CHINESE ACADEMY OF METEOROLOGICAL SCIENCES, Beijing (CN); NORTHWEST A&F UNIVERSITY, Shaanxi (CN)

(21) Appl. No.: 16/980,040

(22) PCT Filed: Aug. 6, 2019
(86) PCT No.: PCT/CN2019/099460

§ 371 Date: Sep. 11, 2020

(30) Foreign Application Priority Data
Jun. 21, 2019 (CN) 201910543250.2

(51) Int. Cl. G06Q 50/02; G06F 30/20

(52) U.S. Cl. CPC G06Q 50/02; G06F 30/20

(57) ABSTRACT

A method for simulating a development date based on a response mechanism and an adaptation mechanism of a crop to an environment, including: collecting crop phenology data observed at a research station; obtaining a day of year of a start date, a quantity of days, and an average temperature, in the development phase, based on the crop phenology data; obtaining a development rate based on the quantity of days in the development phase, where the development rate is a reciprocal of the quantity of days in the development phase; calculating a product of the average temperature and the day of year of the start date of the development phase; and obtaining a regression equation as an equation simulating the development date, through a linear regression algorithm, where the development rate serves as a dependent variable, and the average temperature and the product serve as regressors.

The present application claims priority to Chinese Patent Application No. 201910543250.2, titled “METHOD FOR SIMULATING DEVELOPMENT DATE BASED ON RESPONSE MECHANISM AND ADAPTATION MECHANISM OF CROP TO ENVIRONMENT”, filed on Jun. 21, 2019 with the China National Intellectual Property Administration, which is incorporated herein by reference in its entirety.

### TECHNICAL FIELD

The present disclosure relates to the technical field of agriculture, and in particular to a method for simulating a development date based on a response mechanism and an adaption mechanism of a crop to an environment.

### BACKGROUND

Crop growth simulation, as an emerging edge of technology, is a major development in crop physiology and ecology in recent years. The crop growth simulation describes quantitatively crop growth, crop development, a process of forming a crop yield, and a response of a crop to an environment, based on a principle of systematic analysis and computer simulation technology. Knowledge of crop physiology and ecology is highly synthesized and integrated in a model for the growth simulation, which has a significance of universal application. A successful crop growth model can be widely applied for understanding, predicting, and regulating growth and yields of crops.

A method for simulating a development date is usually applied in a crop model for predicting the development date. Currently reported are various methods for simulating the development dates, most of which are established by describing a response mechanism of a development rate of the crop to an environment. The methods are merely different from each other in a detailed form of a response function. All of these methods consider a temperature as the most important environment factor affecting the development rate. In conventional technology, it is assumed in most simulation methods that an accumulated temperature required by the crop for completing the development period is a constant, when the temperature is within a certain range and other environmental conditions are substantially met. Such assumption is one of most basic theories for these methods for simulating the development dates, and is widely applied in related fields. The prediction result of the development date greatly influences a prediction result of a yield, because the development date is a key factor affecting the yield. Therefore, accurate prediction of development dates of a crop in different environments can provide necessary premises and bases for predicting the yield.

There is further an adaptation mechanism of a crop to an environment, besides the response mechanism. The response mechanism refers to how the environment affects the development date, and the adaptation mechanism refers to how the crop adjusts the development rate actively to adapt to the environment. Only the response mechanism of the crop to the environment is described in most methods for simulating the development date simulation in conventional technology. These methods describe a detailed response of the crop to climate but no adaptation of the crop to the climate, which is one reason of large errors when facing fluctuating environments in the simulation methods in conventional technology. Although many complicated temperature response functions are constructed to improve simulation accuracy, increased complexity of the models does not lead to a significant improvement in simulation accuracy due to the missing adaptation mechanism, and simulation errors facilitate cause systematic deviations. For example, a predicted development date is apt to be later than an actual development date in cold years, while earlier than the actual development date in warm years. In addition, the increased complexity of the models results in problems, such as difficulties in parameterization and application, large uncertainty in simulation results, and a phenomenon of equifinality of different parameters (which refers to similar simulation results are obtained from different combinations of parameters). These problems make it difficult to improve a simulation effect of the models in conventional technology, under an existing framework in which only the response mechanism is described.

The prediction of the development date of a crop is a key basis for predicting a yield. The climate fluctuates dramatically in recent decades, and would fluctuate more dramatically in the foreseeable future as climate change further continues. An assessment on yield would be subject to a systematic deviation, in a case that the simulation of the development date is subject to a system deviation. Therefore, a better method for simulating the development date is required in business of yield prediction and the futures market, so as to meet a requirement on accuracy of yield assessment. It is difficult to apply the simulation methods in conventional technology to scenarios with climate fluctuations, since adaptability of the development date of the crop to the climate is not considered. A method for simulating a development date of a crop based on a response mechanism and an adaptation mechanism has not been reported so far.

### SUMMARY

In view of the above, a method for simulating a development date based on a response mechanism and an adaptation mechanism of a crop to an environment is provided according to embodiments of the present disclosure. Both the response mechanism and the adaptation mechanism are considered in the method, and thereby the development date of the crop can be better simulated in comparison with a model in conventional technology.

It is necessary to find a factor representing adaptability of the crop to the environment, in order to consider the adaptability of the development date to the environment in a method for simulating the development date. It is proposed that a DOY of a start date of the development phase serves as the factor representing the adaptability. The method is proposed based on following ideas.

(1) From a perspective of a crop. In a vegetative growth phase (taking winter wheat as an example), the development date is earlier in a warm year than in previous years, and an impact of an accumulated thermal unit on a development rate is weakened due to the photoperiod and vernalization mechanisms. The development date in a cold year is later than in previous years, and the impact of the accumulated thermal unit on the development rate is increased by the photoperiod and the vernalization mechanisms. The photoperiod and the vernalization apply consistent influences on temperature sensitivity, and both have a positive correlation with the DOY of the development date. Therefore, the photoperiod and the vernalization can be replaced with the DOY in the vegetative growth phase, to modify a temperature response function. In a reproductive growth phase, the crop is capable to avoid high temperatures or killing frosts. Annual occurrence of high temperatures and frosts has an obvious seasonal pattern, and the DOY of a current development date may predict roughly how many days there are left before such occurrence. Therefore, it is also reasonable to use the DOY to adjust temperature sensitivity in the reproductive growth phase.

(2) From a perspective of climate. Climate resources such as radiation, temperature, and rainfall, required in growth and development of plants show significant seasonal changes. Therefore, the DOY can not only represent a climate that has occurred in a year, but also predict a climate that is coming.

(3) From a perspective of adaptability of the crop to the climate. Since the development date of a crop is an important manifestation of adaption of the crop to the environment, it is apparent that the DOY of the development date of the crop can be used in a development model to represent the adaptability of the crop to the environment.

Therefore, the DOY of the development date can serve as the factor representing the adaptability of crops to the environment. The DOY can be coupled into a conventional method, to develop a novel simulation method that considers the response mechanism and the adaptation mechanism of a crop to the climate.

In order to achieve the above objectives, following technical solutions are provided according to embodiments of the present disclosure.

A method for simulating a development date based on a response mechanism and an adaptation mechanism of a crop to an environment is provided according to the present disclosure. The method includes following steps:

(1) collecting crop phenology data observed at a research station;

(2) obtaining a day of year of a start date of a development phase, a quantity of days in the development phase, and an average temperature in the development phase, based on the crop phenology data;

obtaining a development rate based on the quantity of days in the development phase, where the development rate is a reciprocal of the quantity of days in the development phase; and

calculating a product of the average temperature and the day of year of the start date of the development phase;

(3) obtaining values of parameters a, b and c in an equation (1) through linear regression, where the development rate serves as a dependent variable, the average temperature and the product of the average temperature and the day of year of the start date of the development phase serve as regressors,

y=a+bx₁+cx₂ (1),

where y represents the development rate, x₁ represents the average temperature, and x₂ represents the product of the average temperature multiplied by the day of year of the start date of the development phase; and

(4) obtaining an equation for simulating the development date at the research station, based on parameters a, b, and c obtained in the step (3), where

Y=a+(b+c×DOY)×T (2),

Y represents a daily development rate after the start date of the development phase, DOY represents the day of year of the start date of the development phase, and T represents the average temperature.

A method for coupling the response mechanism and the adaptation mechanism into a model for simulating the development date is provided according to embodiments of the present disclosure. In the method, the DOY serves as the factor representing the adaptability of the crop to the environment, and is combined with a simple linear temperature response function, thereby achieving simulation of the response mechanism and the adaptation mechanism. The method is different from the methods of simulating the development date in conventional technology. In conventional technology, it is assumed that the accumulated temperature required for the crop is a constant. In the method according to embodiments of the present disclosure, this assumption is not followed, and the method is not based on the accumulated temperature. Instead, the method is based on a theory that there are both the response mechanism and the adaptive mechanism of the crop to the environment, and a feasible method is proposed to implement the theory. The method considers both the response mechanism and the adaptation mechanism, and thereby simulates the development date of the crop better than the models in conventional technology. The method according to embodiments of the present disclosure can improve prediction accuracy effectively for the development dates in cold years and warm years, thereby providing a good tool for business in which highly precise prediction of development dates and yields are required.

In technical solutions of the present disclosure, the DOY can be replaced with another parameter, which includes a day length or an anomaly (such as an average of emergence dates of multiple years subtracted by an emergence date of a currently simulated year) of the start date (that is, the emergence date in a case of simulating emergence-flowering) of the development phase in a current year. Such two methods have an effect similar to that of the foregoing technical solution, and are essentially similar to the method based on the DOY, as a phenology simulation method coupling with the response mechanism and the adaptation mechanism. Therefore, the technical solution based on the day length or the anomaly of the start date of the development phase in the current year instead of the DOY also falls within the protection scope of the present disclosure.

In a preferable embodiment, the method for simulating the development date further includes a step (5) after the step (4): accumulating the daily development rate obtained in the step (4) from a beginning of simulation, to obtain an accumulated daily development rate, and obtaining the simulated development date based on the accumulated daily development rate.

In a preferable embodiment, obtaining the simulated development date based on the accumulated daily development rate is determining a date at which the accumulated daily development rate exceeds 1 for the first time, as the simulated development date.

According to embodiments of the present disclosure, the development phase is any development phase within a vegetative growth phase or a reproductive growth phase, and does not include a development phase overlapping with both the vegetative growth phase and the reproductive growth phase.

A method for simulating a maturity date based on a response mechanism and an adaptation mechanism of a crop to an environment is further provided according to embodiments of the present disclosure. The method includes following steps:

(1) collecting crop phenology data observed at a research station;

(2) obtaining a day of year of a start date of a reproductive growth phase, a quantity of days in the reproductive growth phase, and an average temperature in the reproductive growth phase, based on the crop phenology data;

obtaining a development rate based on the quantity of days in the reproductive growth phase, where the development rate is a reciprocal of the quantity of days in the reproductive growth phase; and

calculating a product of the average temperature and the day of year of the start date of the reproductive growth phase;

(3) obtaining values of parameters a, b and c in an equation (1) through linear regression, where the development rate serves as a dependent variable, the average temperature and the product of the average temperature and the day of year of the start date of the reproductive growth phase serve as regressors,

y=a+bx₂+cx₂ (1)

where y represents the development rate, x₁ represents the average temperature, and x₂ represents the product of the average temperature multiplied by the day of year of the start date of the reproductive growth phase;

(4) obtaining an equation for simulating the maturity date at the research station, based on parameters a, b, and c obtained in the step (3):

Y=a+(b+c×DOY)×T (2)

where Y represents a daily development rate after the start date of the reproductive growth phase, DOY represents the day of year of the start date of the reproductive growth phase, and T represents the average temperature; and

step (5), accumulating the daily development rate obtained in the step (4) from a beginning of simulation, to obtain an accumulated daily development rate, and determining a date at which the accumulated daily development rate exceeds 1 for the first time, as the simulated maturity date.

In an embodiment of the present disclosure, the start date of the reproductive growth phase is, but is not limited to, a flowering date or a heading date.

In an embodiment of the present disclosure, the reproductive growth phase is, but is not limited to, a flowering-maturity period or a heading-maturity period.

The method for simulating the development date based on the response mechanism and the adaptation mechanism of the crop to the environment is provided according to an embodiment of the present disclosure. The method includes: (1) collecting the crop phenology data observed at the research station; (2) obtaining the day of year of the start date the development phase, the quantity of days in the development phase, and the average temperature in the development phase, based on the crop phenology data; obtaining the development rate based on the quantity of days in the development phase, where the development rate is the reciprocal of the quantity of days in the development phase; and calculating the product of the average temperature and the day of year of the start date of the development phase; (3) obtaining the values of the parameters a, b and c in the equation Y=a+bx₁+cx₂ through linear regression, where the development rate serves as the dependent variable, the average temperature and the product of the average temperature and the day of year of the start date of the development phase serve as the regressors, and where y represents the development rate, x₁ represents the average temperature, and x₂ represents the product of the average temperature multiplied by the day of year of the start date of the development phase; and (4) obtaining an equation for simulating the development date at the research station, based on parameters a, b, and c obtained in the step (3), where Y=a+(b+c×DOY)×T, Y represents a daily development rate after the start date of the development phase, DOY represents the day of year of the start date of the development phase, and T represents the average temperature. With the technical solutions, the following beneficial effects can be achieved.

In the method according to embodiments of the present disclosure, the development rate follows a linear response function with respect to the temperature, and the linear inclination rate in the response function is a linear function of the day of year (DOY) of a previous development stage. In the method, the response function of the development rate to the temperature in different years is adjusted based on the adaptability of the crop in these years. Since the day of year of the development date is a factor representing the adaptability of the crop to the environment, the response mechanism and the adaptation mechanism to the temperature are coupled in a development model according to a coupling manner proposed in the method. Moreover, the method is simple because only 3 parameters are required, and the parameters can be directly obtained from the observation data, avoiding that parameters can only be obtained through iteration or trial-and-error when calculated by a complex response function. The method is suitable for regional and large-scale prediction of the development date.

In the present disclosure, the method for simulating the development date that couples response mechanism and adaptation mechanism is constructed based on an inclination rate in a temperature response function which adjusts linearity with the day of year. The method is capable to adjust a response rate of the development rate of the crop to the environment at any time, based on the development date of the crop. Thereby, the development date can be simulated simply and accurately. In practice, the value of c is positive for different crops and different development periods, which indicates that the development rate is more sensitive to the temperature in case of a later development date, and less sensitive to the temperature in case of an earlier development date. Rice is taken as an example, and the details are described as follows. In a cold year, a heading date is delayed in comparison with those in previous years, thereby the DOY is increased, and values of c×DOY, b+c×DOY, (b+c×DOY)×T, and Y are increased. Therefore, the development rate under a same temperature is higher in the cold year than in the previous years. The quantity of days required from flowering to maturity is reduced due to the higher development rate. Therefore, even in a cold year, there is little difference in the maturity date of the rice in comparison with the previous years. In a warm year, the heading date is advanced, thereby the DOY of the heading date is reduced, and values of (b+c×DOY)×T and Y are reduced. Therefore, the development rate under a same temperature is lower in the warm year than in previous years. The quantity of days required from heading to maturity is increased due to the lower development rate. Therefore, in a warm year, there is little difference in the maturity date of the rice in comparison with the previous years. The prediction results obtained with the method are consistent with the in situ measured data. Therefore, the development date of the crop in a climate fluctuating environment can be more accurately simulated with the model, and thereby a response of a yield can be more accurately assessed. A result obtained from the method is of great significance to grain futures and drafting agricultural measures to deal with the climate change.

### BRIEF DESCRIPTION OF THE DRAWINGS

FIG. 1 shows a flow chart of a method according to an embodiment of the present disclosure (where simulation of a maturity date from a flowering date is taken as an example);

FIG. 2a-2c show a result of simulating maturity dates (simulating a maturity date from flowering) of multiple varieties of three main food crops (winter wheat, rice, and corn) by using a method according to an embodiment of the present disclosure;

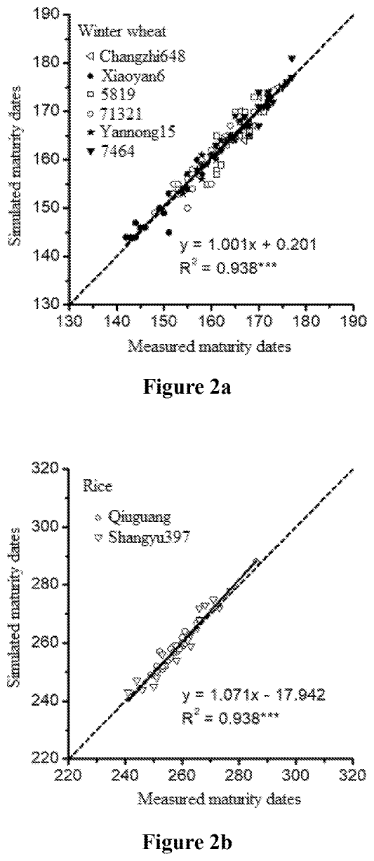

FIG. 3 shows errors and root mean square errors (RMSEs) in simulating a maturity date of rice at Tonghua station according to a first embodiment;

FIG. 4 shows errors and root mean square errors (RMSEs) in simulating a maturity date of rice at Tonghua station according to a first contrast embodiment; and

FIG. 5 shows a trend of errors in simulating a maturity date of rice at Tonghua station with respect to years (a), average temperatures of growing season (b) and heading dates (c), where white circles and dashed lines represent simulation results from a method according to an embodiment of the present disclosure, black dots and solid lines represent simulation results from ORYZA2000, and * and *** represent significance at levels of p<0.05 and p<0.001, respectively.

### DETAILED DESCRIPTION OF THE EMBODIMENTS

A method for simulating a development date based on a response mechanism and an adaptation mechanism of a crop to an environment is provided according to an embodiment of the present disclosure. Those skilled in the art can implement the method by improving process parameters appropriately on reading what is disclosed herein. It should be noted that all similar substitutions and modifications are apparent for those skilled in the art, and shall fall within the scope of the present disclosure. Methods and applications of the present disclosure are described in preferable embodiments. Apparently, those skilled in the art can make modifications or appropriate changes and combinations to the methods and the applications of the present disclosure without departing from the spirit or scope of the present disclosure, to implement and apply the technology according to the present disclosure.

Seeds of crops applied in the method for simulating the development date of the crop based on the response mechanism and the adaptation mechanism according to embodiments of the present disclosure are all commercially available.

Hereinafter the present disclosure is further described in conjunction with embodiments.

### First Embodiment

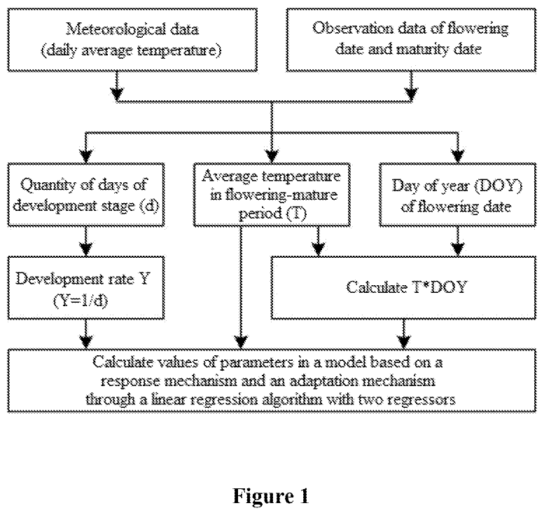

As shown in FIG. 1, a method for simulating a development date based on a response mechanism and an adaptation mechanism of a crop is provided according to the present disclosure.

Agricultural meteorological observation stations, which have observation data of more than fifteen years for development dates of a same variety, are selected based on observation data of development dates of crops from the stations under China Meteorological Administration in recent approximate 30 years. As shown in Table 1, there are 10 stations which have such data, including 6 stations for winter wheat, 1 station for rice, 2 stations for corn, and 1 station for both rice and corn (Tonghua).

TABLE 1
Observation stations and observed crops

| Crop | Station | Variety |
|---|---|---|
| winter | Changzhi | Changzhi648 |
| wheat | Hancheng | Xiaoyan6 |
| | Jincheng | 5819 |
| | Huanghua | 71321 |
| | Laizhou | Yannong15 |
| | Tianshui | 7464 |
| rice | Muling | Shangyu397 |
| | Tonghua | Qiuguang |
| corn | Jiamusi | Dongnong248 |
| | Meihekou | Tiedan4 |
| | Tonghua | Jidan101 |

Herein development dates of all the crops are simulated through a method. For simplicity, the reproductive growth phase (heading-maturity period) of rice at the Tonghua station is taken as an example, to introduce calculation in the method in detail. Methods for simulating other crops and other development dates are similar to this example.

An object of the research is a response and adaptation of maturity date of rice at the Tonghua station to history climate change in China.

1. Meteorological Data and Observation Data of Development Dates of Rice at the Tonghua Station are Collected.

Observation data of the development dates, including the heading date and the maturity date, of the Qiuguang variety is collected at the Tonghua agricultural meteorological observation station under China Meteorological Administration. (In an observation specification for development dates issued by the China Meteorological Administration, it is clearly stated that only the heading date of the rice is observed while the flowering date is not observed, since the flowering date and the heading date of the rice are very close and it is unnecessary to observe both the flowering date and the heading date. Actually, the heading date of the rice approximates the flowering date of other crops, namely, is the start date of the reproductive growth phase, which is commonly recognized in multiple methods for calculating the development dates.) Observation data for 26 years, from 1985 to 2010, is collected. Daily average temperature data in a same period is also collected.

2. Following Calculation Steps (1) to (8) are Performed Based on the Data.

(1) The heading date is converted to a DOY. That is, for each year, January 1st is converted to 1, January 2nd is converted to 2, February 1st is converted to 32, February 2nd is converted to 33, and so forth. December 31 is converted to 365 (for an average year) or 366 (for a leap year). For example, the heading date in 1986 was August 14th, and the DOY corresponding to the heading date is 226.

(2) The quantity of days in a heading-maturity period is calculated. For example, the heading date was August 14 and the maturity date was September 25 in 1986, and thereby the quantity of days in the heading-maturity period is determined to be 43 days.

(3) A development rate in the heading-maturity period is calculated. The development rate is a reciprocal of the quantity of days. In this example, the development rate in 1986 is 1/43.

(4) An average temperature in the heading-maturity period is calculated. Daily average temperatures in the heading-maturity period are accumulated, and then divided by the quantity of days in the heading-maturity period, so as to obtain the average temperature in the period. For example, the average temperature in 1986 was 16.3° C.

(5) A product of the average temperature and the date of year of the heading date is calculated. That is, the average temperature in each year is multiplied by the date of year of the heading date in said year. In this example, the average temperature in the heading-maturity period in 1986 was 16.3° C., the date of year of the heading date, August 14th, is 226, and thereby there is 16.3*226=3684.

(6) The calculation in steps (2) to (5) is performed on the observation data in each year, so as to obtain the development rate, the average temperature, and the product of the average temperature and the day of year of the heading date in each year.

Results are as shown in Table 2.

TABLE 2
Development rates and average temperatures in heading-maturity
periods of rice at Tonghua station in different years

| | | | Average temperature |
|---|---|---|---|
| | | Average | multiplied by the day of |
| | Development | temperature | year of the heading date |
| Year | rate (d⁻¹) | (° C.) | (° C.) |
| 1985 | 0.02439 | 19.1 | 4230 |
| 1986 | 0.02326 | 16.3 | 3684 |
| 1987 | 0.02439 | 18.8 | 4108 |
| 1988 | 0.02703 | 21.3 | 4620 |
| 1989 | 0.02381 | 19.0 | 4127 |
| 1990 | 0.02439 | 19.5 | 4244 |
| 1991 | 0.02381 | 20.4 | 4404 |
| 1992 | 0.02326 | 18.6 | 4096 |
| 1993 | 0.02381 | 18.0 | 3985 |
| 1994 | 0.02439 | 20.3 | 4444 |
| 1995 | 0.02381 | 17.8 | 3956 |
| 1996 | 0.02326 | 18.3 | 4058 |
| 1997 | 0.02273 | 19.3 | 4190 |
| 1998 | 0.02222 | 19.4 | 4218 |
| 1999 | 0.02273 | 19.7 | 4316 |
| 2000 | 0.02326 | 20.0 | 4398 |
| 2001 | 0.02326 | 19.6 | 4295 |
| 2002 | 0.02222 | 18.0 | 3931 |
| 2003 | 0.02222 | 18.4 | 4027 |
| 2004 | 0.02326 | 18.9 | 4165 |
| 2005 | 0.02326 | 19.8 | 4365 |
| 2006 | 0.02381 | 19.3 | 4246 |
| 2007 | 0.02326 | 19.6 | 4312 |
| 2008 | 0.02326 | 19.5 | 4290 |
| 2009 | 0.02273 | 18.6 | 4090 |
| 2010 | 0.02381 | 19.7 | 4422 |

(7) Values of parameters a, b and c in an equation (2) is calculated by using an equation (1). A linear regression algorithm is applied, where the development rate serves as a dependent variable, and the average temperature and the product of the average temperature and the day of year of the heading date serve as regressors. The values of parameters a, b and c in equation (2) are obtained, as shown in Table 3.

y=a+bx₁+cx₂ (1)

y represents the development rate, x₁ represents the average temperature, and x₂ represents the product of the average temperature and the day of year of the heading date.

Y=a+(b+c×DOY)×T (2)

TABLE 3
Parameters of rice at Tonghua station simulated by a method according to an
embodiment of the present disclosure, and a simulation error of the method

| | | | | | | Root mean square |
|---|---|---|---|---|---|---|
| | | | Values of parameters (*10⁻³) | | | error of the |
| | Station | Variety | a | b | c | simulation (d) |
| Crop | Tonghua | Qiuguang | 13.143 | −0.419 | 0.00438 | 1.78 |

(8) A simulation effect of the equation (2) is checked. Based on the values of parameters a, b and c obtained in the step (7), the heading date and the daily average temperature observed in each year are inputted to simulate a maturity date. Taking year 1986 as an example, the date of year of the heading date, August 14th, in this year was 226, the daily average temperature was T, and (a+(b+c×226)×T) at each day after the observed heading date is calculated. For example, the average temperature on August 14th is 20° C., then the development rate on the day is:

(13,143+(−0.419+0.00438×226)×20.0)×10⁻³=0.024.

Development rates at other days are calculated, and results are as shown in Table 4. Values of the development rate are accumulated day by day, and a date at which the accumulated value exceeds 1 for the first time is determined to be the maturity date. As shown in Table 4, the simulated maturity date in 1986 is September 28th. The actual maturity date is September 25th. Thereby, a simulation error (a simulated value subtracted by an actual value) is −3d.

TABLE 4
Daily development rate and accumulated value thereof for
rice at Tonghua station after heading date in 1986

| | | Temperature | | Accumulated |
|---|---|---|---|---|
| Month | Day | (° C.) | Development rate | value |
| 8 | 14 | 20.0 | 0.024 | 0.024 |
| 8 | 15 | 19.5 | 0.024 | 0.048 |
| 8 | 16 | 19.2 | 0.024 | 0.071 |
| 8 | 17 | 20.9 | 0.025 | 0.096 |
| 8 | 18 | 23.1 | 0.026 | 0.122 |
| 8 | 19 | 18.2 | 0.023 | 0.145 |
| 8 | 20 | 16.4 | 0.022 | 0.167 |
| 8 | 21 | 16.8 | 0.022 | 0.189 |
| 8 | 22 | 17.7 | 0.023 | 0.212 |
| 8 | 23 | 17.9 | 0.023 | 0.235 |
| 8 | 24 | 18.7 | 0.023 | 0.258 |
| 8 | 25 | 19.1 | 0.024 | 0.282 |
| 8 | 26 | 18.8 | 0.023 | 0.305 |
| 8 | 27 | 19.2 | 0.024 | 0.329 |
| 8 | 28 | 18.8 | 0.023 | 0.352 |
| 8 | 29 | 15.7 | 0.022 | 0.374 |
| 8 | 30 | 18.3 | 0.023 | 0.397 |
| 8 | 31 | 17.1 | 0.022 | 0.419 |
| 9 | 1 | 19.0 | 0.023 | 0.443 |
| 9 | 2 | 18.6 | 0.023 | 0.466 |
| 9 | 3 | 19.0 | 0.023 | 0.489 |
| 9 | 4 | 18.7 | 0.023 | 0.513 |
| 9 | 5 | 17.8 | 0.023 | 0.536 |
| 9 | 6 | 17.2 | 0.023 | 0.558 |
| 9 | 7 | 16.0 | 0.022 | 0.580 |
| 9 | 8 | 17.2 | 0.023 | 0.603 |
| 9 | 9 | 16.8 | 0.022 | 0.625 |
| 9 | 10 | 17.3 | 0.023 | 0.647 |
| 9 | 11 | 16.2 | 0.022 | 0.669 |
| 9 | 12 | 14.9 | 0.021 | 0.691 |
| 9 | 13 | 15.8 | 0.022 | 0.712 |
| 9 | 14 | 15.4 | 0.022 | 0.734 |
| 9 | 15 | 15.1 | 0.021 | 0.755 |
| 9 | 16 | 14.1 | 0.021 | 0.776 |
| 9 | 17 | 8.3 | 0.018 | 0.794 |
| 9 | 18 | 7.5 | 0.017 | 0.811 |
| 9 | 19 | 11.6 | 0.019 | 0.830 |
| 9 | 20 | 13.7 | 0.021 | 0.851 |
| 9 | 21 | 13.6 | 0.021 | 0.872 |
| 9 | 22 | 10.3 | 0.019 | 0.890 |
| 9 | 23 | 8.1 | 0.018 | 0.908 |
| 9 | 24 | 10.1 | 0.019 | 0.927 |
| 9 | 25 | 11.8 | 0.020 | 0.946 |
| 9 | 26 | 12.9 | 0.020 | 0.966 |
| 9 | 27 | 8.1 | 0.018 | 0.984 |
| 9 | 28 | 7.2 | 0.017 | 1.001 |

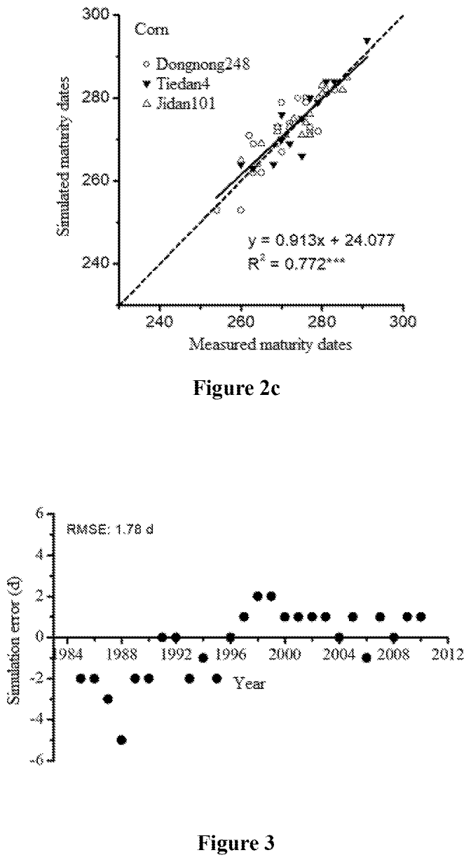

The simulation errors in other years are deduced by analogy. The simulation errors in different year are obtained, as shown in FIG. 3. A root mean square error (RMSE) in simulating the maturity dates of rice at Tonghua station with the method according to embodiments of the present disclosure is calculated, which is 1.78d.

The maturity dates of crops at other research stations are simulated with the same method, and the values of parameters and the root mean square errors of simulations at the 10 stations are as follows.

TABLE 5
Parameters and simulation errors in simulating maturity
dates of varieties of three main food crops with a method
according to an embodiment of the present disclosure

| | | | | | | Root mean square |
|---|---|---|---|---|---|---|
| | | | Values f parameters (*10⁻³) | | | error of the |
| Crop | Station | Variety | a | b | c | simulation (d) |
| winter | Changzhi | Changzhi648 | −3.356 | −0.020 | 0.01334 | 1.96 |
| wheat | Hancheng | Xiaoyan6 | 20.256 | −2.172 | 0.02268 | 2.14 |
| | Jincheng | 5819 | 1.584 | −2.124 | 0.02675 | 2.70 |
| | Huanghua | 71321 | −5.737 | 0.605 | 0.01023 | 2.11 |
| | Laizhou | Yannong15 | 16.592 | −1.706 | 0.01784 | 1.62 |
| | Tianshui | 7464 | 4.557 | 0.834 | 0.00148 | 1.70 |
| rice | Muling | Shangyu397 | 3.162 | −0.462 | 0.00648 | 3.23 |
| | Tonghua | Qiuguang | 13.143 | −0.419 | 0.00438 | 1.78 |
| corn | Jiamusi | Dongnong248 | 3.680 | −2.307 | 0.01441 | 4.85 |
| | Meihekou | Tiedan4 | 0.696 | −1.498 | 0.01118 | 3.67 |
| | Tonghua | Jidan101 | 6.711 | −2.780 | 0.01658 | 2.78 |

From the results, it can be seen that the root mean square error ranges from 1.62d to 4.85d, in simulating the maturity dates of crops with the simulation method according to embodiments of the present disclosure.

### First Contrast Embodiment

An ORYZA2000 model is used to simulate the development date of rice. The ORYZA2000 model is a specific crop model developed by the International Rice Research Institute for simulating growth and development of rice. The ORYZA2000 model is widely used all over the world and is a mainstream model for simulating rice. In the ORYZA2000 model, the development rate at reproductively growth period is only affected by temperature, and it is assumed that accumulated temperature required by the period is a constant. Therefore, there is only one parameter named DVRR in the model. DVRR represents a reciprocal of the accumulated temperature required by the period, that is, contribution of each accumulated thermal unit to the development rate.

The simulation of the reproductive growth period (heading-maturity period) of the rice at the Tonghua station is further taken as an example. DVRR is set to range from 0.0001 to 0.0050, which covers ranges of most varieties. Then, DVRR is optimized in a loop with a stepsize of 0.0001, where a value of DVRR with a minimum root mean square error (RMSE) of simulation errors is determined to be a final value of DVRR. The detailed method is as follows.

1. The DVRR is set to be 0.0001, and a maturity date is simulated based on an actual heading date in 1985 to obtain a simulation error of the maturity date in 1985 (where the simulation error is defined as a simulated value subtracted by an actual value).

2. Then, the maturity date is simulated from an actual heading date in 1986 to obtain a simulation error of the maturity date in 1986. Simulation in other years until 2010 is performed by analogy.

3. Simulation errors of the rice at Tonghua station for 26 years, from 1985 to 2010, are obtained for DVRR being 0.0001. A RMSE of the simulation errors is calculated and recorded as RMSE_{0.0001}.

4. The DVRR is increased by one stepsize, 0.0001, to obtain DVRR equal to 0.0002. Again, the maturity date is simulated again based on the actual heading date in 1985, to obtain a simulation error of the maturity date in 1985. Simulation in other years until 2010 is performed by analogy, to obtain simulation errors of the rice at the Tonghua station for the 26 years, from 1985 to 2010, for DVRR being 0.0002. A RMSE of the simulation errors is calculated and recorded as RMSE_{0.0002}.

5. The DVRR is further increased by one stepsize to obtain DVRR equal to 0.0003. Maturity dates for the 26 years are further simulated to obtain a simulation error in each year and a RMSE. The RMSE is recorded as RMSE_{0.0003}.

6. The DVRR is further increased, until the DVRR is equal to 0.0050.

7. Comparison is made among RMSE_{0.0001}, RMSE_{0.0002}, . . . , RMSE_{0.0050}, and the DVRR corresponding to the minimum RMSE is determined as a final value of the DVRR. The simulation errors for all years, corresponding to the minimum RMSE, are determined to be the final simulation errors. The final simulation errors reflect a maximum simulation capability of the ORYZA2000 model in simulating the maturity date of the rice at the Tonghua station.

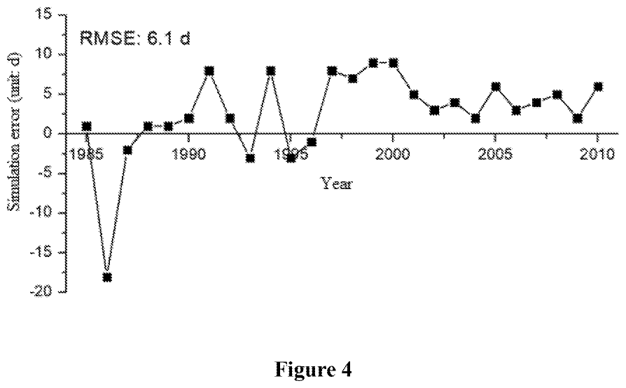

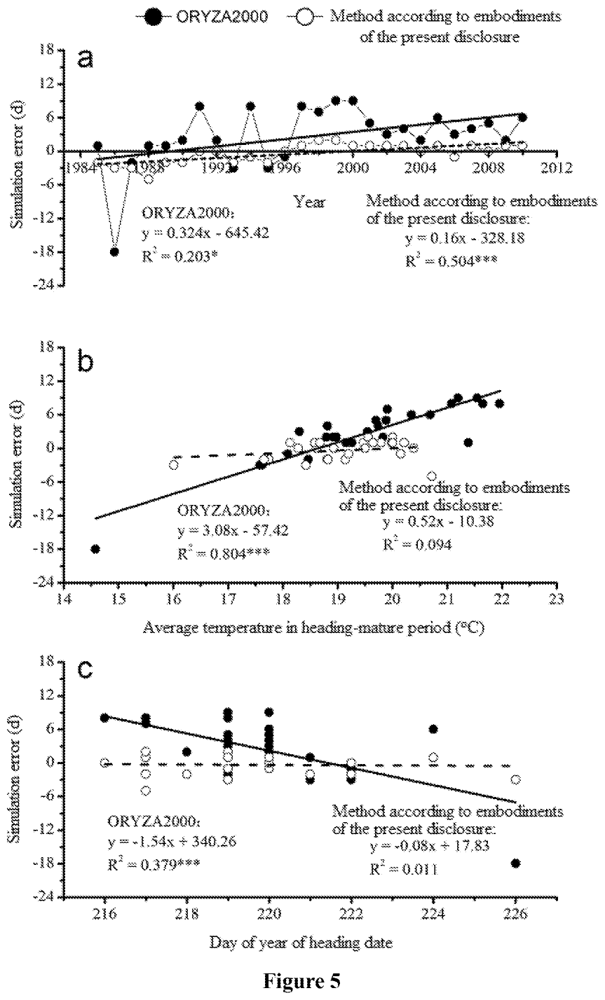

Results are as shown in FIGS. 4 and 5.

FIG. 4 shows the final simulation errors of the ORYZA2000 model. The RMSE is 6.1d, which is much higher than the RMSE, 1.78d, of the method according to embodiments of the present disclosure. The simulation error of the ORYZA2000 model is −18d in 1986, a year having the latest heading date.

In simulating the development date, better is not only a higher accuracy, but also a smaller systematic deviation of the simulation error. A large systematic deviation of the simulation error indicates that the model has a large defect in mechanism. FIG. 5 shows a comparison between the simulation results of the two methods. In comparison with the method adopted in the ORYZA2000 model, the method according to embodiments of the present disclosure reduces the simulation error, and reduces a trend of the simulation error with respect to time (as shown in FIG. 5a), temperature (as shown in FIG. 5b), and the day of year of the heading date (a shown in FIG. 5c). Therefore, the method according to embodiments of the present disclosure is comprehensively better than the simulation method in conventional technology. A main reason lies in coupling of the response mechanism and the adaptation mechanism of crop phenology to the environment.

Result Analysis

The aforementioned rice at the Tonghua station in 1986 is taken as an example. The simulation error of the method in the first embodiment is −3d, and the simulation error with the method in the first contrast embodiment without considering the adaptation mechanism is −18d.

A reason lies in that the year 1986 is the coldest year in the 26 years. Thereby, the heading date at August 14th is the latest heading date in the 26 years. An actual effective accumulated temperature above 8° C. is only 355° C·d in this year, which is the lowest among the 26 years. An average effective accumulated temperature of the Qiuguang rice of at the Tonghua station is 473° C·d. Therefore, when applying model based on only the response mechanism, an additional effective accumulated temperature of 118° C·d is required for the rice to mature in 1986. In the mature season of the rice, the temperature keeps decreasing, and the effective accumulated temperature in each day keeps decreasing, resulting in the simulation error of −18d. After the adaptation mechanism is considered, the latest heading date in the year leads to a largest c×DOY in the equation (2), and thereby the development rate in this year is higher than in other years under the same temperature. The increased development rate eventually leads to a simulation error of −3d. A case in a warm year can be obtained by analogy.

As indicated by the comparison of the methods in the first embodiment and the first contrast embodiment, such method can simulated the development date of the crop better than models in conventional technology, since both the response mechanism and the adaptation mechanism are considered in the method according to embodiments of the present disclosure. The method according to embodiments of the present disclosure can effectively improve prediction accuracy for the development dates in cold years and warm years, and thereby provide a good tool for business which requires highly precise prediction of development dates and yields.

The above description is only preferable embodiments of the present disclosure. It should be noted that those skilled in the art can make improvements and modifications without departing from the principle of the present disclosure. These improvements and modifications should also fall within the protection scope of the present disclosure.

1. A method for simulating a development date based on a response mechanism and an adaptation mechanism of a crop to an environment, comprising:
collecting crop phenology data observed at a research station;
obtaining a day of year (DOY) of a start date of a development phase, a quantity of days in the development phase, and an average temperature in the development phase, based on the crop phenology data;
obtaining a development rate based on the quantity of days in the development phase, wherein the development rate is a reciprocal of the quantity of days in the development phase; and
calculating a product of the average temperature and the DOY of the start date of the development phase;
obtaining values of parameters a, b and c in an equation y=a+bx₁+cx₂ through linear regression, wherein the development rate serves as a dependent variable, the average temperature and the product of the average temperature and the DOY of the start date of the development phase serve as regressors,
wherein y represents the development rate, x₁ represents the average temperature, and x₂ represents the product of the average temperature multiplied by the DOY of the start date of the development phase; and
obtaining an equation for simulating the development date at the research station, based on the obtained parameters a, b, and c obtained, wherein the equation for simulating the development date is:
Y=a+(b+c×DOY)×T,
Y represents a daily development rate after the start date of the development phase, DOY represents the DOY of the start date of the development phase, and T represents the average temperature.

2. The method according to claim 1, wherein after obtaining the equation for simulating the development date at the research station, the method further comprises:
accumulating the obtained daily development rate from the start date of the development phase, to obtain an accumulated daily development rate, and determining the simulated development date based on the accumulated daily development rate.

3. The method according to claim 2, wherein the simulated development date is determined to be a date at which the accumulated daily development rate exceeds 1 for the first time.

4. The method according to claim 1, wherein the development phase is within a vegetative growth phase or a reproductive growth phase, and does not overlap with both the vegetative growth phase and the reproductive growth phase.

5. The method according to claim 1, wherein the development date is a maturity date, and the development phase is a reproductive growth phase.

6. The method according to claim 5, wherein the start date of the reproductive growth phase is a flowering date or a heading date.

7. The method according to claim 5, wherein the reproductive growth phase is a flowering-maturity period or a heading-maturity period.

8. The method according to claim 2, wherein the development phase is within a vegetative growth phase or a reproductive growth phase, and does not overlap with both the vegetative growth phase and the reproductive growth phase.

9. The method according to claim 3, wherein the development phase is within a vegetative growth phase or a reproductive growth phase, and does not overlap with both the vegetative growth phase and the reproductive growth phase.

10. The method according to claim 2, wherein the development date is a maturity date, and the development phase is a reproductive growth phase.

11. The method according to claim 3, wherein the development date is a maturity date, and the development phase is a reproductive growth phase.
